(19) United States
(12) Patent Application Publication
(10) Pub. No.: US 2009/0108410 A1
(43) Pub. Date: Apr. 30, 2009

(54) SEMICONDUCTOR DEVICE

(76) Inventors: Koji Takemura, Osaka (JP); Takahiro Kumakawa, Kyoto (JP); Yoshihiro Matsushima, Kyoto (JP)

Correspondence Address: MCDERMOTT WILL & EMERY LLP, 600 13TH STREET, NW, WASHINGTON, DC, 20005-3096, US

(21) Appl. No.: 12/137,018

(22) Filed: Jun. 11, 2008

(30) Foreign Application Priority Data
Oct. 31, 2007 (JP) 2007-283733
Mar. 28, 2008 (JP) 2008-087906

(51) Int. Cl. H01L 23/544

(52) U.S. Cl. 257/620; 257/E23.179

(57) ABSTRACT

A semiconductor device includes a semiconductor substrate, a diffusion layer conductive film formed on the semiconductor substrate, an interlayer insulating film layered on the semiconductor substrate, an interconnect pattern and a via pattern formed in the interlayer insulating film, a plurality of circuit regions formed in the semiconductor substrate, and a scribe region formed around the circuit regions and separating the circuit regions from each other. The diffusion layer conductive film is not formed at least in a region to which laser light is emitted in the scribe region.

### CROSS REFERENCE TO RELATED APPLICATION

This application claims priority under 35 U.S.C. §119 on Patent Application No. 2007-283733 filed in Japan on Oct. 31, 2007 and Patent Application No. 2008-87906 filed in Japan on Mar. 28, 2008, the entire contents of which are hereby incorporated by reference.

### BACKGROUND OF THE INVENTION

1. Field of the Invention

The invention relates to a semiconductor device having a multilayer interconnect structure.

2. Background Art

In a semiconductor device having a multilayer interconnect structure, interconnect layers are generally formed by embedding a metal film in grooves formed in an interlayer insulating film of each interconnect layer (a damascene method). In the damascene method, grooves are formed in a semiconductor substrate, and a metal film is then deposited on the whole surface of the semiconductor substrate. An unnecessary metal film is removed by, e.g., a Chemical Mechanical Polishing (CMP) method so that the metal film is left only in the grooves. In the CMP method used in the damascene method, the polishing rate varies depending on the interconnect pattern or the like to be formed in an interlayer insulating film. More specifically, the polishing rate is higher in a region of a sparse interconnect pattern or the like than in a region of a dense interconnect pattern or the like. Therefore, the film thickness is smaller in the region of a sparse interconnect pattern or the like than in the region of a dense interconnect pattern or the like. Preventing such variation in interconnect film thickness due to the difference in polishing rate is important to suppress variation in final interconnect film thickness. A method of providing a pseudo interconnect pattern as a dummy pattern in the region of a sparse interconnect pattern or the like is used to prevent such variation in interconnect film thickness. Uneven polishing of patterns (dishing) in the CMP process can be prevented by this method.

For example, Japanese Laid-Open Patent Publication No. 2004-235357 describes a semiconductor device that has a uniform dummy pattern in a scribe region and circuit regions of a semiconductor substrate in order to prevent dishing in a CMP process.

FIGS. 23A and 23B show a scribe region that serves as a cutting region for dividing a semiconductor wafer into chips in a conventional semiconductor device. FIG. 23A is a plan view of the scribe region provided between circuit regions and shows a top surface of one of a plurality of first interlayer insulating films in the scribe region. FIG. 23B is a cross-sectional view taken along line XXIIIb-XXIIIb in FIG. 23A and shows a cross section of the interlayer insulating film with protective films and the like formed thereon.

As shown in FIG. 23A, a plurality of circuit regions 2 are formed spaced apart from each other on a main surface of a semiconductor substrate 1. Functional elements (not shown) are formed in the circuit regions 2. A seal ring 3 made of a conductive material is formed around each circuit region 2. A scribe region 4 is formed between the seal rings 3 respectively surrounding adjacent circuit regions 2. The scribe region 4 serves as a cutting region for dicing the semiconductor substrate 1 into individual circuit regions 2.

As shown in FIG. 23B, first interlayer insulating films 6 and second interlayer insulating films 7 are alternately formed on the main surface of the semiconductor substrate 1. Interconnects (not shown) made of a conductive material are formed in the first interlayer insulating films 6 in each circuit region 2, and vias (not shown) made of a conductive material are formed in the second interlayer insulating films 7 in each circuit region 2. A dummy pattern 30 is formed in the first interlayer insulating films 6 in the scribe region 4. The dummy pattern 30 is an evenly distributed isolated pattern (island-shaped pattern) and is made of a conductive material. Dishing in the CMP process is prevented by forming the evenly distributed dummy patterns 30 in the scribe region 4.

Japanese Laid-Open Patent Publication No. 2007-48995 describes a method for preventing generation of chippings in a dicing process. In this method, a peeling prevention groove is formed by emitting laser light on both sides of, and at a distance from, a dicing line on a semiconductor wafer.

This Publication mentions formation of a dummy pattern for preventing dishing and the process of forming a peeling prevention groove by laser light, but does not mention the relation among a diffusion layer conductive film that is formed in a scribe region, arrangement of an interconnect dummy pattern, and a laser grooving method. In the laser grooving method, when laser light transmits to a diffusion layer, the laser light is absorbed by a diffusion layer conductive film formed in the diffusion layer, causing melting and volume expansion of the diffusion layer conductive film. As a result, an interlayer insulating film is peeled in a wide range on the diffusion layer conductive film. Such peeling causes problems such as water entering chips, and chippings are also produced from the peeled part in a dicing process performed after the laser grooving process. As a result, the semiconductor device is degraded in quality and reliability.

### SUMMARY OF THE INVENTION

In view of the above problems, it is an object of the invention to prevent defects from being generated by chippings that are produced in a dicing process of a semiconductor substrate (wafer) by a laser grooving method.

In order to achieve the above object, in a semiconductor device of the invention, no diffusion layer conductive film is formed in a region to which laser light is emitted in a dicing process or the like in a scribe region. In the case where the diffusion layer conductive film is formed in the scribe region, a dummy pattern is formed in an interlayer insulating film so that laser light is not emitted to the diffusion layer.

More specifically, a semiconductor device according to a first aspect of the invention includes: a semiconductor substrate; a diffusion layer conductive film formed on the semiconductor substrate; an interlayer insulating film layered on the semiconductor substrate; an interconnect pattern and a via pattern formed in the interlayer insulating film; a plurality of circuit regions formed in the semiconductor substrate; and a scribe region formed around the circuit regions and separating the circuit regions from each other. The diffusion layer conductive film is not formed at least in a region to which laser light is emitted in the scribe region.

In the semiconductor device of the first aspect of the invention, the diffusion layer conductive film is not formed in the region to which laser light is emitted in a laser grooving process of the scribe region. Therefore, laser light is not absorbed by the diffusion layer conductive film, and melting and volume expansion of the diffusion layer conductive film do not occur, whereby peeling of the interlayer insulating film can be prevented. As a result, the semiconductor device can be prevented from being degraded in quality and reliability by laser light emission.

In the semiconductor device of the first aspect of the invention, it is preferable that the diffusion layer conductive film is not formed in the scribe region.

In the semiconductor device of the first aspect of the invention, it is preferable that the interconnect pattern and the via pattern are not formed in the scribe region.

In this structure, the scribe region to which laser light is emitted does not have any material that absorbs laser light. Therefore, the interlayer insulating film can be uniformly melted by laser light, whereby peeling of the interlayer insulating film can be prevented.

In the semiconductor device of the first aspect of the invention, it is preferable that the interconnect pattern or the via pattern is formed in the scribe region other than a region around a center line of the scribe region, and the interconnect pattern or the via pattern formed in the scribe region has an increased distance across the region around the center line toward a top layer of the interlayer insulating film.

In this structure, the diffusion layer conductive film and the conductive members such as an interconnect pattern and a via pattern are not formed in a region to which laser light is emitted in a laser grooving process in the scribe region. Therefore, the region to which laser light is emitted does not have any material that absorbs laser light. Accordingly, the interlayer insulating film can be uniformly melted by laser light, whereby peeling of the interlayer insulating film can be prevented. An interconnect pattern or a via pattern is formed in the scribe region other than the region to which laser light is emitted. Therefore, dishing can be prevented in a CMP process.

A semiconductor device according to a second aspect of the invention includes: a semiconductor substrate; a diffusion layer conductive film formed on the semiconductor substrate; a plurality of interlayer insulating films layered on the semiconductor substrate; an interconnect pattern and a via pattern formed in the interlayer insulating films; a plurality of circuit regions formed in the semiconductor substrate; and a scribe region formed around the circuit regions and separating the circuit regions from each other. At least a region to which laser light is emitted in the scribe region is covered by the interconnect patterns or the via patterns respectively formed in a plurality of interlayer insulating films, when viewed two-dimensionally.

In the semiconductor device of the second aspect of the invention, laser light is first absorbed by the interconnect pattern or the via pattern in a laser grooving process. As the laser light is absorbed by the interconnect pattern or the via pattern, heat is generated and the interlayer insulating film is melted. More specifically, an upper layer of the interlayer insulating film is first melted and the melted part is removed by sublimation. The melted part continuously expands in the interlayer insulating film. As a result, the interlayer insulating film can be uniformly melted and removed by laser light in a wide range of the scribe region. Even when a diffusion layer conductive film is formed in the scribe region to which laser light is emitted, the laser light is blocked by the interconnect pattern or the via pattern formed in the interlayer insulating film on the diffusion layer conductive film. Accordingly, the semiconductor device can be prevented from being degraded in quality and reliability by laser light emission.

In the semiconductor device of the second aspect of the invention, it is preferable that the scribe region is entirely covered by the interconnect patterns or the via patterns respectively formed in the plurality of interlayer insulating films, when viewed two-dimensionally.

In the semiconductor device of the second aspect of the invention, the diffusion layer conductive film may be formed in the scribe region.

In this structure, laser light in a laser grooving process is absorbed by the interconnect pattern or the via pattern formed in the interlayer insulating film on the diffusion layer conductive film, and the laser light is thus blocked by the interconnect pattern or the via pattern. Therefore, laser light is not absorbed by the diffusion layer conductive film, and melting and volume expansion of the diffusion layer conductive film do not occur, whereby peeling of the interlayer insulating film can be prevented. As a result, the semiconductor device can be prevented from being degraded in quality and reliability by laser light emission.

In the semiconductor device of the second aspect of the invention, it is preferable that the interconnect patterns respectively formed in the plurality of interlayer insulating films in the scribe region overlap each other at least at their respective ends, when viewed two-dimensionally.

In this structure, the amount of a conductive material that forms the interconnect patterns can be reduced, and the quantity of laser light in a laser grooving process can be relatively reduced. As a result, stable operation can be implemented.

In the semiconductor device of the second aspect of the invention, it is preferable that the interconnect patterns respectively formed in the plurality of interlayer insulating films in the scribe region have their respective edges aligned each other, when viewed two-dimensionally.

In this structure, the amount of the conductive material that forms the interconnect patterns can further be reduced, and the quantity of laser light in a laser grooving process can be relatively reduced. As a result, stable operation can be implemented.

In the semiconductor device of the second aspect of the invention, it is preferable that the interconnect pattern formed in the scribe region is formed in upper two or more of the plurality of interlayer insulating films.

In this structure, the amount of the conductive material that forms the interconnect patterns can be reduced, and the quantity of laser light in a laser grooving process can be relatively reduced. As a result, stable operation can be implemented. Moreover, the conductive material is not melted in the lower ones of the plurality of interlayer insulating films. Therefore, the interlayer insulating film can be uniformly melted and removed by laser light in a wide range of the scribe region.

In the semiconductor device of the second aspect of the invention, it is preferable that the interconnect pattern formed in the scribe region is formed in lower two or more of the plurality of interlayer insulating films.

In this structure, a finer interconnect pattern can be formed than in the case where the interconnect pattern is formed in upper ones of the plurality of first interlayer insulating films. Therefore, heat generation and melting of the interlayer insulating film can be more uniformly caused by laser light. Accordingly, the interlayer insulating film can be uniformly melted and removed by the laser light in a wide range of the scribe region.

A semiconductor device according to a third aspect of the invention includes: a semiconductor substrate; a diffusion layer conductive film formed on the semiconductor substrate; an interlayer insulating film layered on the semiconductor substrate and having an interconnect pattern; a plurality of circuit regions formed in the semiconductor substrate; and a scribe region formed around the circuit regions and separating the circuit regions from each other. The interconnect pattern having a flat plate shape is formed at least in a region to which laser light is emitted in the scribe region.

In the semiconductor device of the third aspect of the invention, laser light that is emitted in a laser grooving process can be reliably absorbed by the flat plate interconnect pattern. An upper layer of the interlayer insulating film is first melted and the melted part is removed. Melting of the interlayer insulating film by the laser light then successively proceeds toward a lower layer of the interlayer insulating film. Therefore, the interlayer insulating film can be uniformly melted and removed by the laser light in a wide range of the scribe region. Even when the diffusion layer conductive film is formed in the scribe region to which laser light is emitted, the laser light is blocked by the interconnect pattern formed in the interlayer insulating film on the diffusion layer conductive film. Accordingly, the semiconductor device can be prevented from being degraded in quality and reliability by laser light emission.

A semiconductor device according to a fourth aspect of the invention includes: a semiconductor substrate; a diffusion layer conductive film formed on the semiconductor substrate; an interlayer insulating film layered on the semiconductor substrate; an interconnect pattern and a via pattern formed in the interlayer insulating film; a plurality of circuit regions formed in the semiconductor substrate; and a scribe region formed around the circuit regions and separating the circuit regions from each other. At least a region to which laser light is emitted in the scribe region is covered by the interconnect patterns and the via patterns respectively formed in a plurality of interlayer insulating films, when viewed two-dimensionally.

In the semiconductor device of the fourth aspect of the invention, laser light is first absorbed by the interconnect pattern and the via pattern in a laser grooving process. As the laser light is absorbed by the interconnect pattern and the via pattern, heat is generated and the interlayer insulating film is melted. More specifically, an upper layer of the interlayer insulating film is first melted and the melted part is removed by sublimation. The melted part continuously expands in the interlayer insulating film. As a result, the interlayer insulating film can be uniformly melted and removed by the laser light in a wide range of the scribe region. Since the laser light is blocked by the interconnect pattern and the via pattern formed in the interlayer insulating film, the semiconductor device can be prevented from being degraded in quality and reliability by laser light emission.

In the semiconductor device of the fourth aspect of the invention, it is preferable that the interconnect pattern and the via pattern are formed in the plurality of interlayer insulating films so as to cover the entire scribe region when viewed two-dimensionally.

In the semiconductor device of the fourth aspect of the invention, it is preferable that the interconnect pattern is formed in the entire scribe region, and the via pattern is formed only in an upper layer of the interlayer insulating film in a region around a central line of the scribe region.

In this structure, the interconnect pattern and the via pattern are formed in an upper layer of the interlayer insulating film which has a larger film thickness. Melting of the interlayer insulating film by the laser light successively expands from an upper layer toward a lower layer of the interlayer insulating film. Therefore, the interlayer insulating film can be uniformly melted and removed.

In the semiconductor device of the fourth aspect of the invention, the diffusion layer conductive film may be formed in the scribe region.

In this structure, laser light in a laser grooving process is absorbed by the interconnect pattern and the via pattern formed in the interlayer insulating film on the diffusion layer conductive film, and the laser light is thus blocked by the interconnect pattern and the via pattern. Therefore, the laser light is not absorbed by the diffusion layer conductive film, and melting and volume expansion of the diffusion layer conductive film do not occur, whereby peeling of the interlayer insulating film can be prevented. As a result, the semiconductor device can be prevented from being degraded in quality and reliability by laser light emission.

In the semiconductor device of the fourth aspect of the invention, it is preferable that the interconnect pattern and the via pattern are connected to each other.

As has been described above, in the semiconductor device of the invention, an interlayer insulating film can be uniformly removed by laser light in a dicing process of a semiconductor substrate (wafer) by a laser grooving method. Therefore, generation of chipping defects can be prevented.

### BRIEF DESCRIPTION OF THE DRAWINGS

FIG. 1 is a plan view of a wafer-level semiconductor device according to a first embodiment of the invention;

FIG. 2 is a plan view of a scribe region of the semiconductor device according to the first embodiment of the invention;

FIG. 3 is a cross-sectional view taken along line III-III in FIG. 2;

FIG. 4 is a cross-sectional view after a laser grooving process is performed in the scribe region of the semiconductor device according to the first embodiment of the invention;

FIG. 5 is a cross-sectional view of a scribe region of the semiconductor device according to the first embodiment of the invention;

FIGS. 6A and 6B are plan views of a scribe region in a semiconductor device according to a second embodiment of the invention, where FIG. 6A shows a first interlayer insulating film having a first dummy pattern, and FIG. 6B is a plan view of a first interlayer insulating film having a second dummy pattern;

FIG. 7 is a cross-sectional view taken along line VII-VII in FIG. 6;

FIG. 8 is a cross-sectional view after a laser grooving process is performed in the scribe region of the semiconductor device according to the second embodiment of the invention;

FIG. 9 is a cross-sectional view of a scribe region in a semiconductor device according to a first modification of the second embodiment of the invention;

FIG. 10 is a cross-sectional view of a scribe region in a semiconductor device according to a second modification of the second embodiment of the invention;

FIG. 11 is a cross-sectional view of a scribe region in a semiconductor device according to a third modification of the second embodiment of the invention;

FIG. 12 is a cross-sectional view of a scribe region in a semiconductor device according to a fourth modification of the second embodiment of the invention;

FIG. 13 is a cross-sectional view of a scribe region in a semiconductor device according to a fifth modification of the second embodiment of the invention;

FIG. 14 is a cross-sectional view of a scribe region in a semiconductor device according to a sixth modification of the second embodiment of the invention;

FIG. 15 is a cross-sectional view of a scribe region in a semiconductor device according to a seventh modification of the second embodiment of the invention;

FIG. 16 is a cross-sectional view of a scribe region in a semiconductor device according to the seventh modification of the second embodiment of the invention;

FIG. 17 is a cross-sectional view of a scribe region in a semiconductor device according to an eighth modification of the second embodiment of the invention;

FIG. 18 is a cross-sectional view of a scribe region in a semiconductor device according to the eighth modification of the second embodiment of the invention;

FIG. 19 is a cross-sectional view of a scribe region in a semiconductor device according to a third embodiment of the invention;

FIG. 20 is a cross-sectional view of a scribe region in a semiconductor device according to a fourth embodiment of the invention;

FIG. 21 is a cross-sectional view of a scribe region in a semiconductor device according to a first modification of the fourth embodiment of the invention;

FIG. 22 is a cross-sectional view of a scribe region in a semiconductor device according to a second modification of the fourth embodiment of the invention; and

FIG. 23A is a plan view of a scribe region in a semiconductor device of a conventional example, and FIG. 23B is a cross-sectional view taken along line XXIIIb-XXIIIb in FIG. 23A.

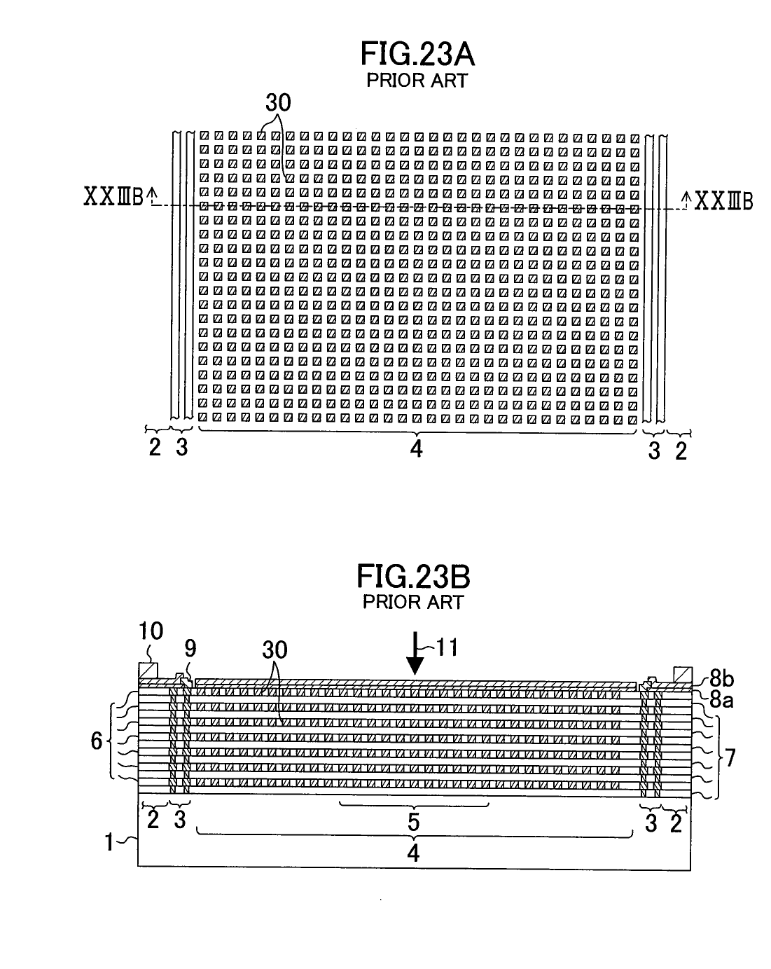

### DETAILED DESCRIPTION OF THE PREFERRED EMBODIMENTS

### First Embodiment

A first embodiment of the invention will be described with reference to the figures.

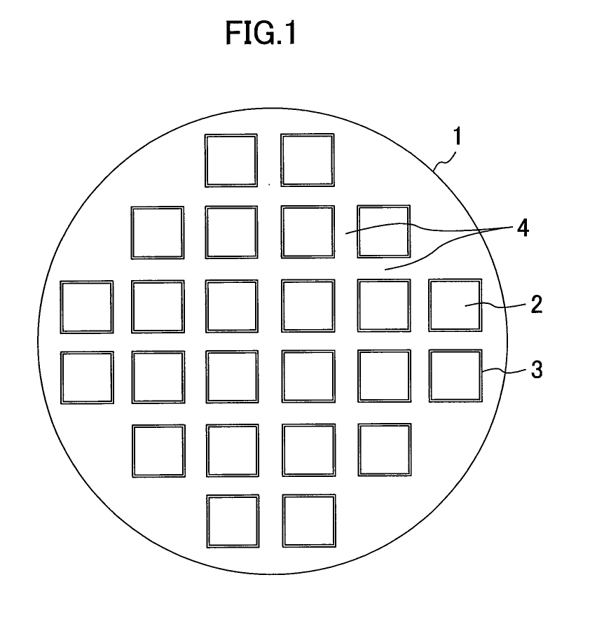

FIG. 1 is a plan view of a wafer-level semiconductor device according to the first embodiment.

As shown in FIG. 1, in the semiconductor device of the first embodiment, a plurality of circuit regions 2 having functional elements (not shown) electrically connected by interconnects and vias connected to the interconnects are arranged at a distance from each other in a matrix pattern in a wafer-state semiconductor substrate 1. Each circuit region 2 is surrounded by an annular seal ring 3 including at least one line of line vias. A “line via” herein indicates, for example, a line-shaped via connected along a line-shaped interconnect formed in a first interlayer insulating film. Two lines of line vias are formed in the first embodiment. A scribe region 4 is formed between adjacent circuit regions, that is, around each seal ring 3, as a cutting region used in a dicing process for cutting out the circuit regions 2 from the semiconductor device 1.

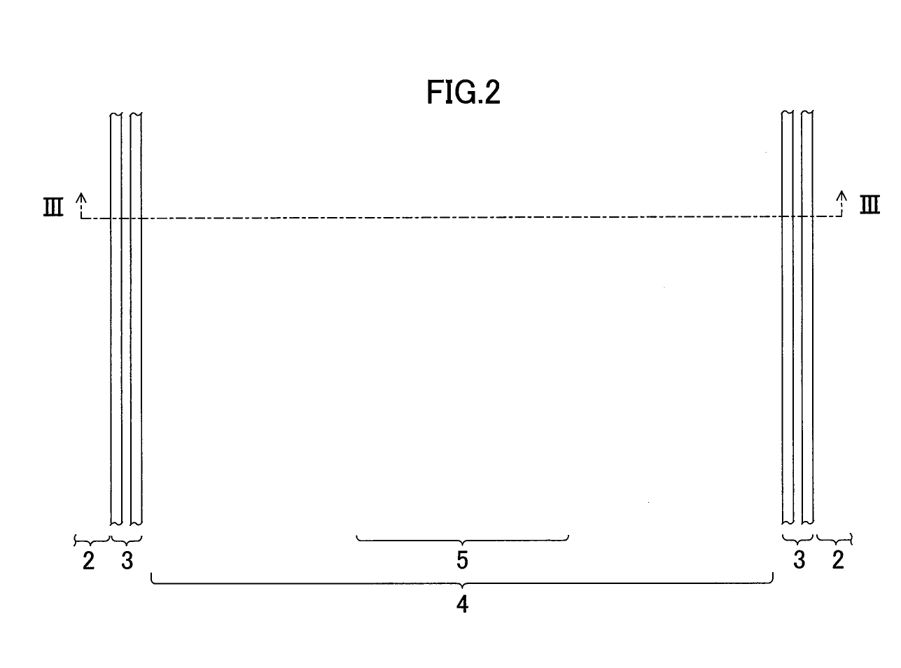

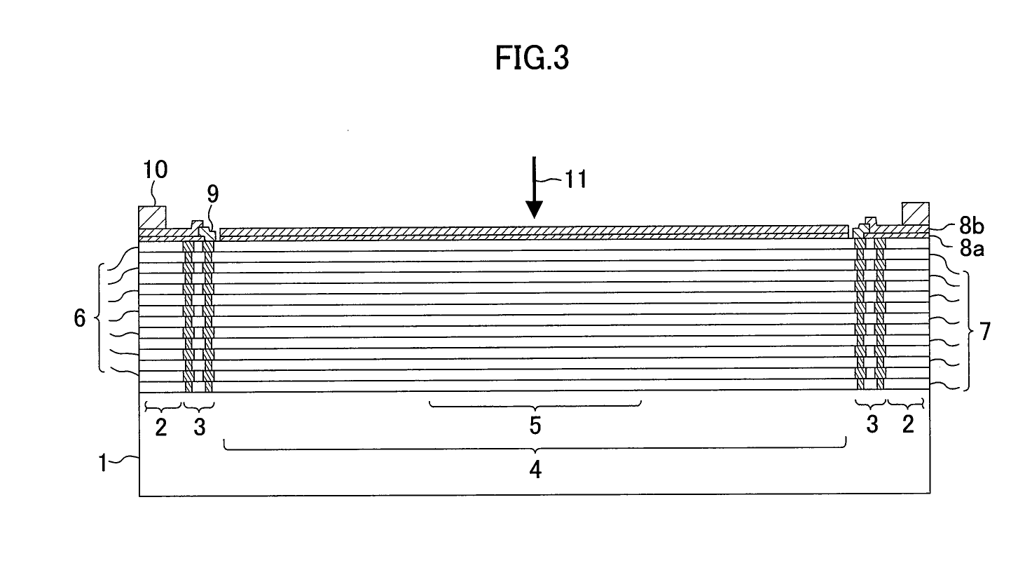

FIG. 2 is a partial enlarged plan view of the scribe region 4 provided between adjacent circuit regions 2. FIG. 3 is a cross-sectional view taken along line III-III in FIG. 2. FIG. 2 shows a top surface of one of a plurality of first interlayer insulating films in the scribe region 4.

As shown in FIG. 2, the scribe region 4 is formed between adjacent circuit regions 2. In other words, the scribe region 4 is formed around each seal ring 3 surrounding the respective circuit region 2. A blade dicing region 5 located in the middle of the scribe region 4 between adjacent circuit regions 2 is cut in a dicing process.

As shown in FIG. 3, the semiconductor device of the first embodiment has an alternately layered structure of first interlayer insulating films 6 and second interlayer insulating films 7 on the semiconductor substrate 1. The first interlayer insulating films 6 in each circuit region 2 include interconnects and dummy interconnects, and the second interlayer insulating films 7 in each circuit region 2 include vias and dummy vias. An interconnect pattern formed by interconnects and vias, and a dummy pattern formed by dummy interconnects and dummy vias are formed in each circuit region 2. The dummy pattern is made of the same conductive material as the interconnect pattern. Since the circuit regions 2 are only partially shown in FIG. 3, the interconnect pattern and the dummy pattern are not shown in FIG. 3. In the first embodiment, no diffusion layer conductive film is formed in the scribe region 4 and no dummy pattern formed by dummy interconnects and dummy vias and made of the same conductive material as the interconnect pattern is formed in the first interlayer insulating films 6 and the second interlayer insulating films 7 in the scribe region 4.

A first protective film 8a and a second protective film 8b are sequentially formed on a top layer of the interlayer insulating film having a plurality of layers. The first protective film 8a and the second protective film 8b are made of an insulating material. The first protective film 8a and the second protective film 8b are disconnected between each circuit region 2 and the scribe region 4. An embedded film 9 made of a conductive material is formed at the end of the first protective film 8a in each circuit region 2. A resin protective film 10 made of an insulating material is formed on the second protective film 8b in each circuit region 2. Although not shown in the figure, an etching blocking film, a cap film, or the like may be formed between the first interlayer insulating film 6 and the second interlayer insulating film 7.

As shown in FIG. 3, in a dicing process, laser light 11 for performing a laser grooving process is emitted to the blade dicing region 5 located in the middle of the scribe region 4 between adjacent circuit regions 2.

As described above, in the semiconductor device of the first embodiment, no diffusion layer conductive film is formed between the semiconductor substrate 1 and the interlayer insulating film, and no interconnects and no vias are formed in the scribe region 4. In the semiconductor device of the first embodiment, the scribe region 4 having no conductive members such as a diffusion layer conductive film, interconnects, and vias is cut in a laser grooving process.

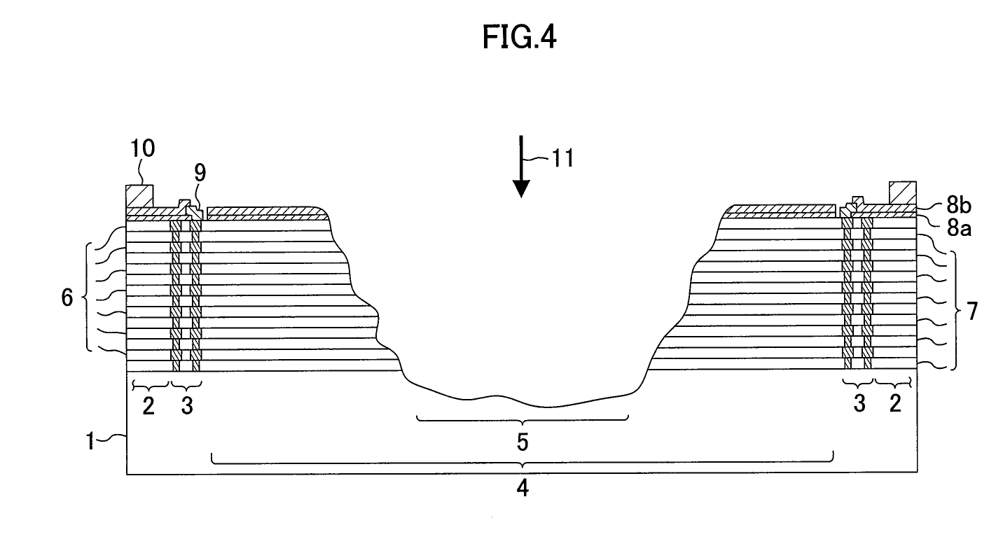

FIG. 4 shows a cross-sectional structure after a laser grooving process is performed on the scribe region 4 having no diffusion layer conductive film, no interconnects, no vias, and the like.

As shown in FIG. 4, the scribe region 4 of the first embodiment does not have any conductive members, such as a diffusion layer conductive film, which are made of a material that absorbs laser light 11. Therefore, the plurality of first interlayer insulating films 6 and the plurality of second interlayer insulating films 7 can be uniformly melted by the laser light 11 in a wide range of the scribe region 4. Such uniform melting prevents peeling of the interlayer insulating film. Moreover, by emitting the laser light 11 to the scribe region 4 for an appropriate length of time, a groove can be formed at the surface of the scribe region 4 in the semiconductor substrate 1. In other words, a region having no interlayer insulating film is formed in the blade dicing region 5. A blade dicing process is then performed in the blade dicing region 5. Since the first interlayer insulating films 6 and the second interlayer insulating films 7 which are likely to generate chippings have already been removed in the blade dicing region 5 in the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

In the first embodiment, the width of the scribe region 4 is, for example, about 60 μm to about 150 μm, and the width of the blade dicing region 5 located in the middle of the scribe region 4 is about the same as or slightly larger than the width of a dicing blade. For example, the width of the blade dicing region 5 is, for example, about 30 μm to about 70 μm.

The first interlayer insulating films 6 and the second interlayer insulating films 7 can be generally made of an insulating material such as TEOS (Tetra Ethyl Ortho Silicate) or FSG (Fluoro Silicate Glass). Instead of an insulating material such as TEOS or FSG, the first interlayer insulating films 6 and the second interlayer insulating films 7 may be made of various low dielectric constant films such as silicon oxycarbide (SiOC) or a porous film. The first interlayer insulating films 6 and the second interlayer insulating films 7 may be made of the same material or different materials.

For simplicity, the first interlayer insulating films 6 and the second interlayer insulating films 7 are shown to have the same thickness in FIGS. 3 and 4. However, the first interlayer insulating films 6 and the second interlayer insulating films 7 may either have the same thickness or different thicknesses. For example, the first interlayer insulating films 6 and the second interlayer insulating films 7 located close to the lower part of the layered structure, that is, located close to the semiconductor substrate 1, may be made of a low dielectric constant film having a thickness of about 100 nm to about 300 nm, and the first interlayer insulating films 6 and the second interlayer insulating films 7 located close to the upper part of the layered structure may be made of an interlayer insulating film, such as TEOS, having a thickness of about 300 nm to about 1,500 nm. The first interlayer insulating films 6 and the second interlayer insulating films 7 in the middle part of the layered structure may be made of an interlayer insulating film, such as TEOS, having a thickness of about 200 nm to about 500 nm.

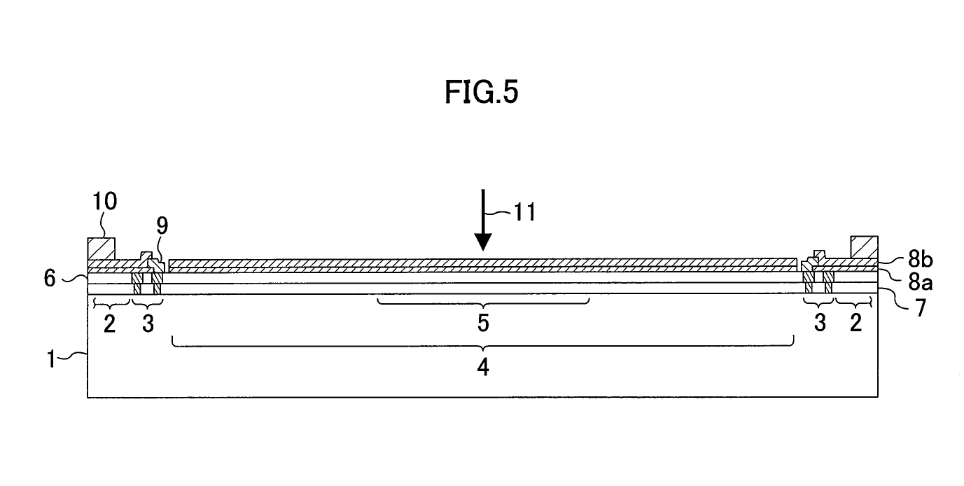

In the first embodiment, the interlayer insulating film in the scribe region 4 is formed by a plurality of layers. As shown in FIG. 5, however, the interlayer insulating film may alternatively be formed by a first interlayer insulating film 6 and a second interlayer insulating film 7.

Dummy interconnects and dummy vias that form dummy patterns can be formed in each circuit region 2 simultaneously with a process of forming interconnects and vias that form interconnect patterns in each circuit region 2 by using a damascene method or the like. The interconnects and dummy interconnects and the vias and dummy vias can be made of a conductive material such as copper or copper alloy. A diffusion preventing barrier film (not shown) made of a thin film such as titanium nitride (TiN) may be formed at each interface between the first interlayer insulating film 6 and the second interlayer insulating film 7.

The first protective film 8a and the second protective film 8b formed on the top surface of the topmost first interlayer insulating film 6 are generally made of silicon nitride (SiN) or the like having a pad portion (not shown) made of a conductive material such as aluminum (Al) in an opening. A two-layer structure of the protective films 8a and 8b are used in this embodiment. However, a single-layer structure or a three or more layer structure may alternatively be used. The embedded film 9 formed at the end of the first protective film 8a in each circuit region 2 and embedded in each gap in the first protective film 8a and the second protective film 8b may be made of a conductive material such as Al. For example, the embedded film 9 can be formed simultaneously with the pad portion in a process of forming the pad portion. This structure reduces damages such as chippings produced by cutting in a dicing process.

In the first embodiment, the seal ring 3 is formed as a double seal ring around each circuit region 2 of the semiconductor substrate 1 and is formed by alternately forming line-shaped (linear) interconnect patterns and line vias as described above. Since the seal ring 3 of this structure seals each circuit region 2 from the outside, contamination of the circuit regions 2 with water, impurities, and the like can be prevented. The seal ring 3 can be made of the same material in the same process as the interconnect patterns formed in the circuit regions 2. The seal ring 3 need not necessarily be a double seal ring, but may be a single seal ring or a triple or more seal ring.

### Second Embodiment

A second embodiment of the invention will now be described with reference to the figures. In the embodiment and modifications described below, the same elements as those of the first embodiment are denoted with the same reference numerals and characters, and description thereof will be omitted. In the second embodiment, a dummy pattern formed by dummy interconnects or dummy vias is formed in the scribe region 4.

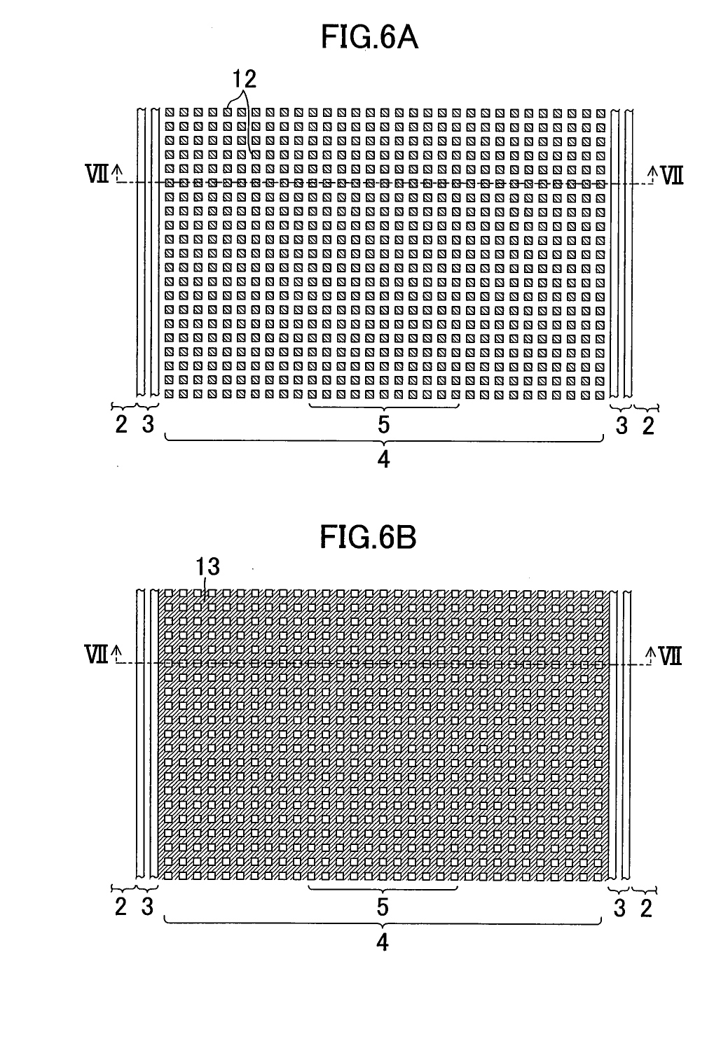

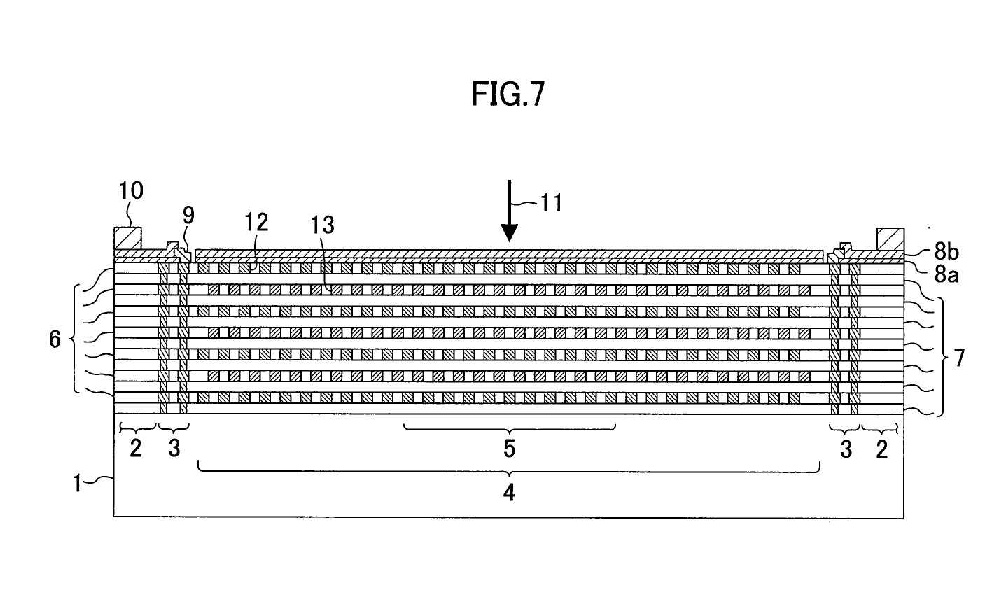

FIGS. 6A and 6B are partial enlarged plan views of a scribe region 4 provided between adjacent circuit regions 2. FIG. 6A shows one of a plurality of interlayer insulating films 6 which has a first dummy pattern 12 formed by an interconnect pattern. FIG. 6B shows one of the plurality of first interlayer insulating films 6 which has a second dummy pattern 13 formed by an interconnect pattern. FIG. 7 shows a cross-sectional view taken along line VII-VII in FIGS. 6A and 6B.

As shown in FIGS. 6A, 6B, and 7, the first dummy pattern 12 formed in the first interlayer insulating films 6 has a grid pattern of the same conductive material as the interconnect pattern, and the second dummy pattern 13 formed in the first interlayer insulating films 6 has an inverted pattern of the conductive material with respect to the first dummy pattern 12. The first dummy pattern 12 and the second dummy pattern 13 are provided so that every part of the scribe region 4, especially of the blade dicing region 5, has a dummy pattern, when viewed two-dimensionally. However, a diffusion layer conductive film is not provided. By thus providing the first dummy pattern 12 and the second dummy pattern 13, laser light 11 is blocked by the conductive material in a laser grooving process, and the scribe region 4 in the semiconductor substrate 1 is covered by the conductive material. Note that copper, aluminum, tungsten, or the like is used as the conductive material.

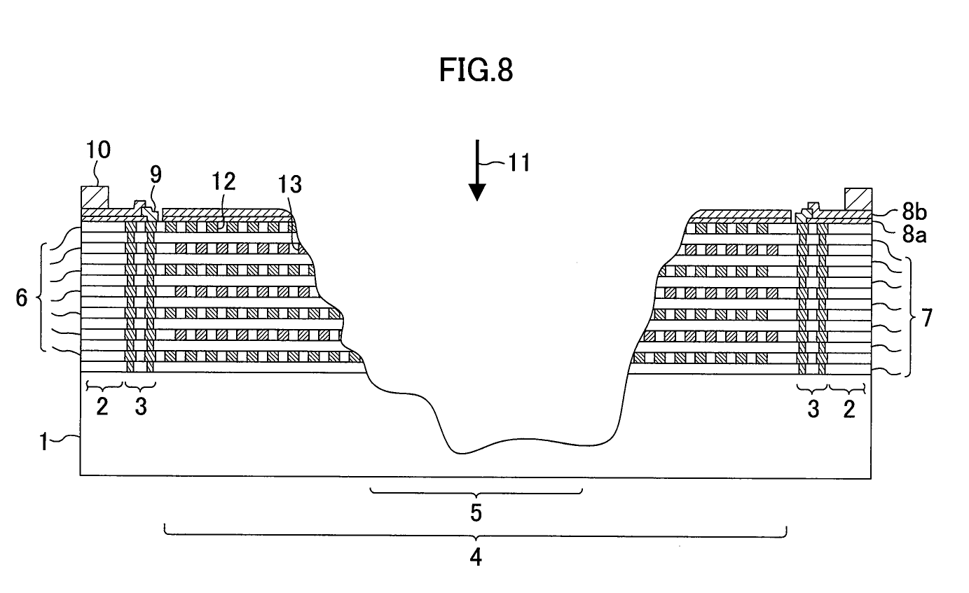

FIG. 8 shows a cross-sectional structure after the laser grooving process is performed on the scribe region 4 in the second embodiment.

As shown in FIG. 8, by emitting laser light 11 to the scribe region 4 for an appropriate length of time, the first interlayer insulating films 6 and the second interlayer insulating films 7 can be melted and a groove can be formed in the surface of the semiconductor substrate 1.

With this structure, the laser light 11 is first absorbed by the first dummy pattern 12 or the second dummy pattern 13 in the laser grooving process. As the laser light 11 is absorbed by the dummy pattern, heat is generated and the interlayer insulating film is melted. More specifically, an upper part of the layered structure of the first interlayer insulating films 6 and the second interlayer insulating films 7 is first melted and the melted part is removed by sublimation. The melted part continuously expands in the layered structure of the first interlayer insulating films 6 and the second interlayer insulating films 7. As a result, the first interlayer insulating films 6 and the second interlayer insulating films 7 can be uniformly melted and removed by the laser light 11 in a wide range of the scribe region 4. In this way, a laser grooving process can be performed while preventing peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

In the second embodiment, the first dummy pattern 12 and the second dummy pattern 13 is formed by an interconnect pattern. However, the first dummy pattern 12 and the second dummy pattern 13 may alternatively be formed by a via pattern.

The dummy interconnects or dummy vias of the first dummy pattern 12 and the second dummy pattern 13 can be formed in the scribe region 4 simultaneously with a process of forming an interconnect pattern or a via pattern in the circuit regions 2 by a damascene process or the like, by using the same material.

In the second embodiment, the first dummy pattern 12 and the second dummy pattern 13 are formed so that dummy interconnects or dummy vias are arranged in a matrix pattern. However, the dummy interconnects or dummy vias may be arranged in a pattern other than the matrix pattern as long as the first dummy pattern 12 and the second dummy pattern 13 cover the scribe region 4.

The scribe region 4 may be covered by a combination of two or more dummy patterns.

In the second embodiment, the dummy patterns are formed only in the first interlayer insulating films 6. However, the dummy patterns may be formed in the second interlayer insulating films 7.

(First Modification of the Second Embodiment)

Hereinafter, a first modification of the second embodiment of the invention will be described with reference to the figures. The first modification of the second embodiment is characterized in that a diffusion layer conductive film 14 is formed between the semiconductor substrate 1 and the interlayer insulating film.

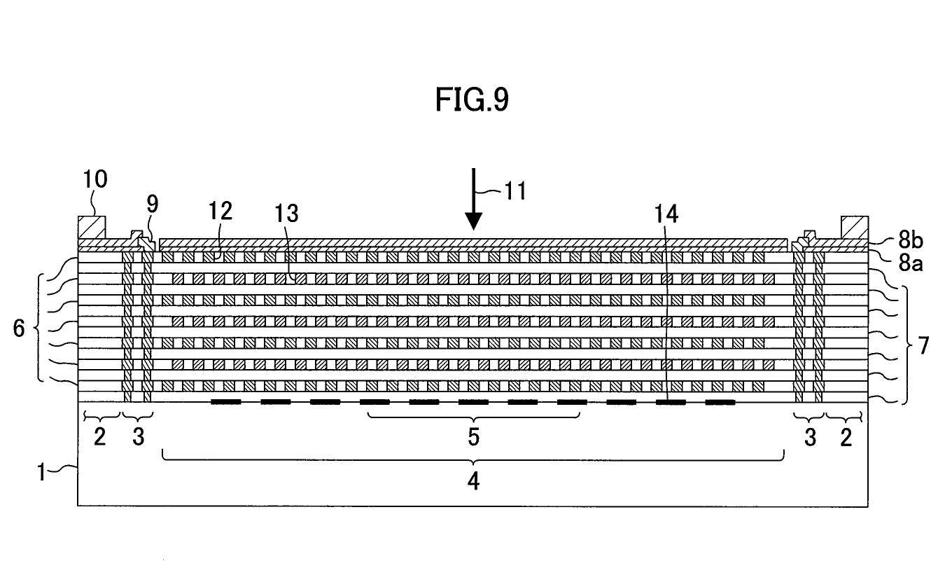

FIG. 9 is a cross-sectional view of a semiconductor device according to the first modification of the second embodiment. Like FIGS. 3 and 7, FIG. 9 shows a scribe region 4 provided between adjacent circuit regions 2.

As shown in FIG. 9, the semiconductor device of the first modification further includes a diffusion layer conductive film 14 formed between the semiconductor substrate 1 and the interlayer insulating film in the scribe region 4, in addition to the structure of the second embodiment. The diffusion layer conductive film 14 may be made of polysilicon, tungsten, a nickel compound, or the like.

In the first modification of the second embodiment, the first dummy pattern 12 and the second dummy pattern 13 cover the scribe region 4 in the semiconductor substrate 1 even though the diffusion layer conductive film 14 is formed. Therefore, laser light 11 is first absorbed by the first dummy pattern 12 or the second dummy pattern 13 in the laser grooving process. As the laser light 11 is absorbed by the dummy pattern, heat is generated and the interlayer insulating film is melted. This is the same as in the second embodiment. More specifically, an upper part of the layered structure of the first interlayer insulating films 6 and the second interlayer insulating films 7 is first melted and the melted part is removed by sublimation. The melted part continuously expands in the layered structure of the first interlayer insulating films 6 and the second interlayer insulating films 7. As a result, the first interlayer insulating films 6 and the second interlayer insulating films 7 can be uniformly melted and removed by the laser light 11 in a wide range of the scribe region 4. The interlayer insulating film has been melted and removed before the laser light 11 is emitted to the diffusion layer conductive film 14. Therefore, the interlayer insulating film is not affected by melting of the diffusion layer conductive film 14. As a result, peeling of the interlayer insulating film can be prevented.

A blade dicing process is then performed in the blade dicing region 5. As in the first embodiment, since the first interlayer insulating films 6 and the second interlayer insulating films 7 which are likely to generate chippings have already been removed in the blade dicing region 5 in the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

(Second Modification of the Second Embodiment)

A second modification of the second embodiment will now be described with reference to the figures.

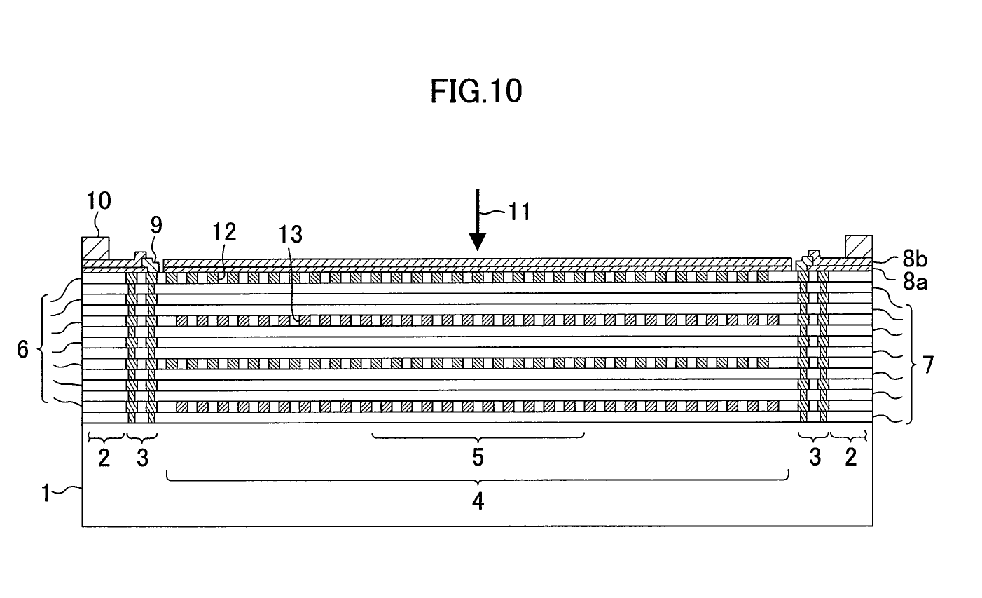

FIG. 10 is a cross-sectional view of a semiconductor device according to the second modification of the second embodiment and shows a scribe region 4 provided between adjacent circuit regions 2.

As shown in FIG. 10, in the semiconductor device of the second modification, a first dummy pattern 12 and a second dummy pattern 13 are formed in the first interlayer insulating films 6 as in the second embodiment. However, a first interlayer insulating film 6 having no dummy pattern is provided between a first interlayer insulating film 6 having a first dummy pattern 12 and a first interlayer insulating film 6 having a second dummy pattern 13. In this structure as well, the first dummy pattern 12 and the second dummy pattern 13 cover the scribe region 4 in the semiconductor substrate. In other words, the first dummy pattern 12 and the second dummy pattern 13 are arranged so that every part of the scribe region 4 has the first dummy pattern 12 or the second dummy pattern 13 when viewed two-dimensionally.

With this structure, the laser light 11 is first absorbed by the first dummy pattern 12 or the second dummy pattern 13 in the laser grooving process. As the laser light 11 is absorbed by the dummy pattern, heat is generated and the interlayer insulating film is melted. More specifically, an upper part of the layered structure of the first interlayer insulating films 6 and the second interlayer insulating films 7 is first melted and the melted part is removed by sublimation. The melted part continuously expands in the layered structure of the first interlayer insulating films 6 and the second interlayer insulating films 7. As a result, the first interlayer insulating films 6 and the second interlayer insulating films 7 can be uniformly melted and removed by the laser light 11 in a wide range of the scribe region 4. In this way, a laser grooving process can be performed while preventing peeling of the interlayer insulating film.

Even when a diffusion layer conductive film is formed between the semiconductor substrate 1 and the interlayer insulating film, the interlayer insulating film has been melted and removed before the laser light 11 is emitted to the diffusion layer conductive film, as in the first modification of the second embodiment. Therefore, melting of the diffusion layer conductive film does not cause any influence on the interlayer insulating film, such as peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

In the second modification, a first interlayer insulating film 6 having no dummy pattern is provided between a first interlayer insulating film 6 having a first dummy pattern 12 and a first interlayer insulating film 6 having a second dummy pattern 13. However, the invention is not limited to this structure. In other words, the structure of the second modification is not limited as long as the scribe region 4 is covered by a combination of two or more dummy patterns. For example, a dummy pattern formed in the second interlayer insulating films 7 may be combined with a dummy pattern formed in the first interlayer insulating films 6 so as to cover the scribe region 4.

An interlayer insulating film in which dummy patterns are formed can be appropriately selected according to the interconnect pattern or via pattern formed in the circuit regions 2.

(Third Modification of the Second Embodiment)

A third modification of the second embodiment of the invention will now be described with reference to the figures.

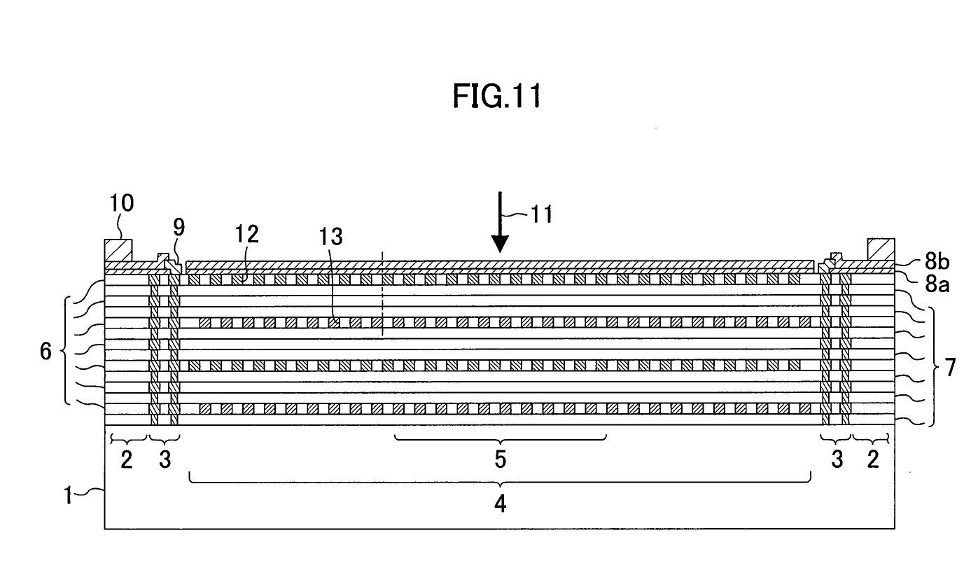

FIG. 11 is a cross-sectional view of a semiconductor device according to a third modification of the second embodiment and shows a scribe region 4 provided between adjacent circuit regions 2.

As shown in FIG. 11, in the semiconductor device of the third modification, a first dummy pattern 12 and a second dummy pattern 13 formed in the interlayer insulating films 6 overlap each other only at their edges. As in the second modification, the semiconductor device of the third modification includes first interlayer insulating films 6 having no dummy pattern.

In this structure, the scribe region 4 is covered by the dummy patterns when viewed two-dimensionally, and the total amount of dummy patterns formed in the scribe region 4 can be reduced. Accordingly, the quantity of laser light 11 to be used in a laser grooving process can be reduced, thereby enabling stable operation. The first interlayer insulating films 6 and the second interlayer insulating films 7 can thus be uniformly melted and removed by the laser light 11 in a wide range of the scribe region 4. As a result, peeling of the interlayer insulating film can be prevented.

In the third modification of the second embodiment, the first dummy pattern 12 and the second dummy pattern 13 overlap each other only at their edges. However, the same effects can be obtained even when the respective edges of the first dummy pattern 12 and the second dummy pattern 13 are aligned with each other.

Even when a diffusion layer conductive film is formed between the semiconductor substrate 1 and the interlayer insulating film, the interlayer insulating film has been melted and removed before the laser light 11 is emitted to the diffusion layer conductive film, as in the first modification of the second embodiment. Therefore, melting of the diffusion layer conductive film does not cause any influence on the interlayer insulating film, such as peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

As in the second embodiment, a dummy pattern different from the first dummy pattern 12 and the second dummy pattern 13 may be used. Two or more dummy patterns may be combined if the dummy patterns are formed so as to overlap each other at their edges and to cover the scribe region 4. A dummy pattern may be formed in the second interlayer insulating films 7 and may be combined with a dummy pattern formed in the first interlayer insulating films 6.

(Fourth Modification of the Second Embodiment)

A fourth modification of the second embodiment of the invention will now be described with reference to the figures.

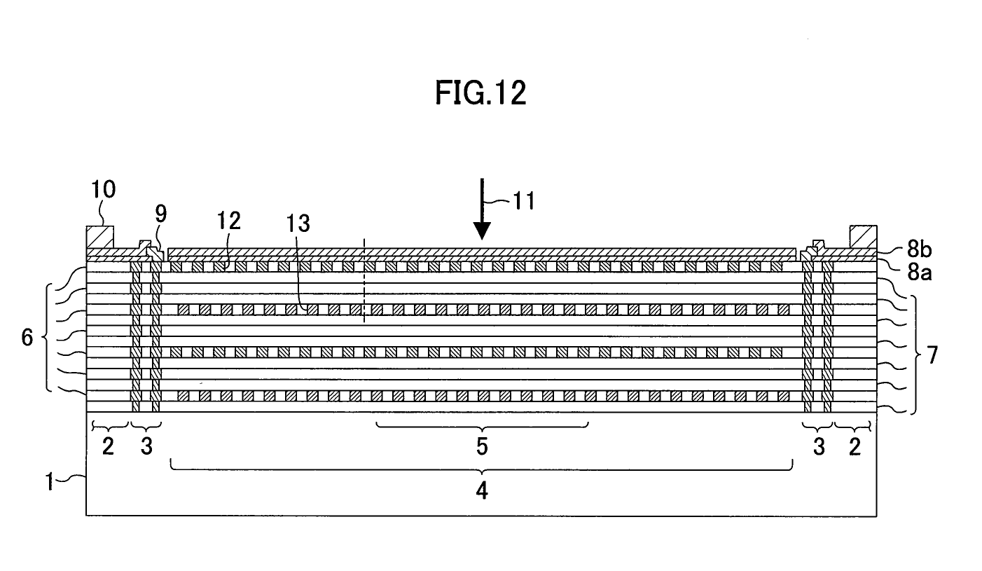

FIG. 12 is a cross-sectional view of a semiconductor device according to a fourth modification of the second embodiment and shows a scribe region 4 provided between adjacent circuit regions 2.

As shown in FIG. 12, in the semiconductor device of the fourth modification, a first dummy pattern 12 and a second dummy patter 13 are formed in the first interlayer insulating films 6 so that their respective edges are not aligned with each other. As in the second modification, the semiconductor device of the fourth modification includes first interlayer insulating films 6 having no dummy pattern.

In this structure, the scribe region 4 is approximately covered by a pair of first dummy pattern 12 and second dummy pattern 13 when viewed two-dimensionally. The scribe region 4 can be entirely covered by a combination of the pair of first dummy pattern 12 and second dummy pattern 13 with another pair of first dummy pattern 12 and second dummy pattern 13. The total amount of dummy patterns formed in the scribe region 4 can thus be reduced. Accordingly, the quantity of laser light 11 to be used in a laser grooving process can be relatively reduced, enabling stable operation. Even with this structure, the first interlayer insulating films 6 and the second interlayer insulating films 7 can be uniformly melted and removed by the laser light 11 in a wide range of the scribe region 4. A laser grooving process can thus be performed while preventing peeling of the interlayer insulating film.

Even when a diffusion layer conductive film is formed between the semiconductor substrate 1 and the interlayer insulating film, the interlayer insulating film has been melted and removed before the laser light 11 is emitted to the diffusion layer conductive film, as in the first modification of the second embodiment. Therefore, melting of the diffusion layer conductive film does not cause any influence on the interlayer insulating film, such as peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

Note that, like the second embodiment and the modifications described above, the invention is not limited to the structure of FIG. 12.

(Fifth Modification of the Second Embodiment)

A fifth modification of the second embodiment of the invention will now be described with reference to the figures.

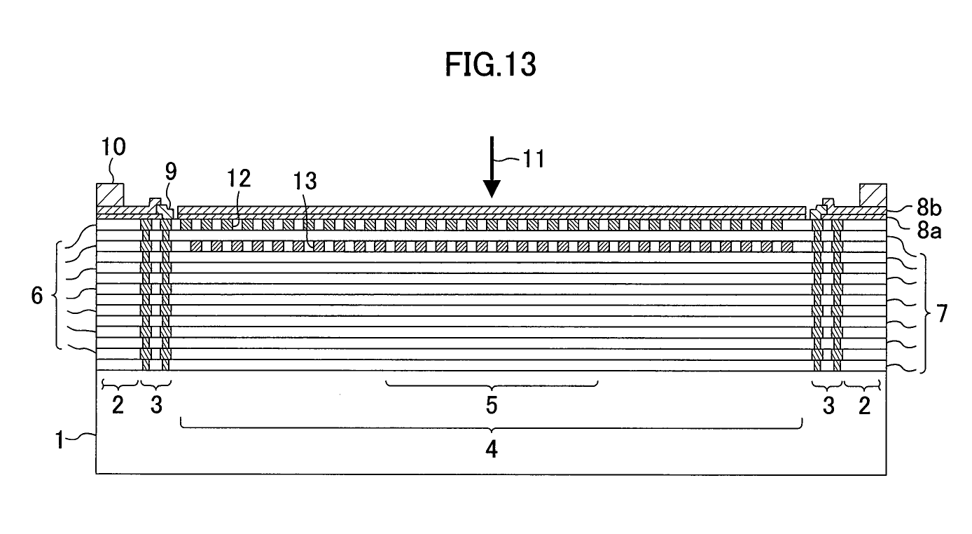

FIG. 13 is a cross-sectional view of a semiconductor device according to the fifth modification of the second embodiment and shows a scribe region 4 provided between adjacent circuit regions 2.

As shown in FIG. 13, the semiconductor device of the fifth modification is characterized in that a first dummy pattern 12 and a second dummy pattern 13 are respectively formed in the upper two of a plurality of first interlayer insulating films 6 formed on a semiconductor substrate 1.

In this structure, the scribe region 4 can be covered by the dummy patterns when viewed two-dimensionally even though the total amount of dummy patterns formed in the scribe region 4 is reduced. As a result, the quantity of laser light 11 to be used in a laser grooving process can be relatively reduced, enabling stable operation. Moreover, since no dummy pattern is formed in the lower first interlayer insulating films 6 and the lower second interlayer insulating films 7 formed on the semiconductor substrate 1, melting of dummy metal does not occur in the lower part of the interlayer insulating film. Accordingly, the first interlayer insulating films 6 and the second interlayer insulating films 7 can be uniformly melted and removed by the laser light 11 in a wide range of the scribe region 4. A laser grooving process can thus be performed while preventing peeling of the interlayer insulating film.

Even when a diffusion layer conductive film is formed between the semiconductor substrate 1 and the interlayer insulating film, the interlayer insulating film has been melted and removed before the laser light 11 is emitted to the diffusion layer conductive film, as in the first modification of the second embodiment. Therefore, melting of the diffusion layer conductive film does not cause any influence on the interlayer insulating film, such as peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

(Sixth Modification of the Second Embodiment)

A sixth modification of the second embodiment of the invention will now be described with reference to the figures.

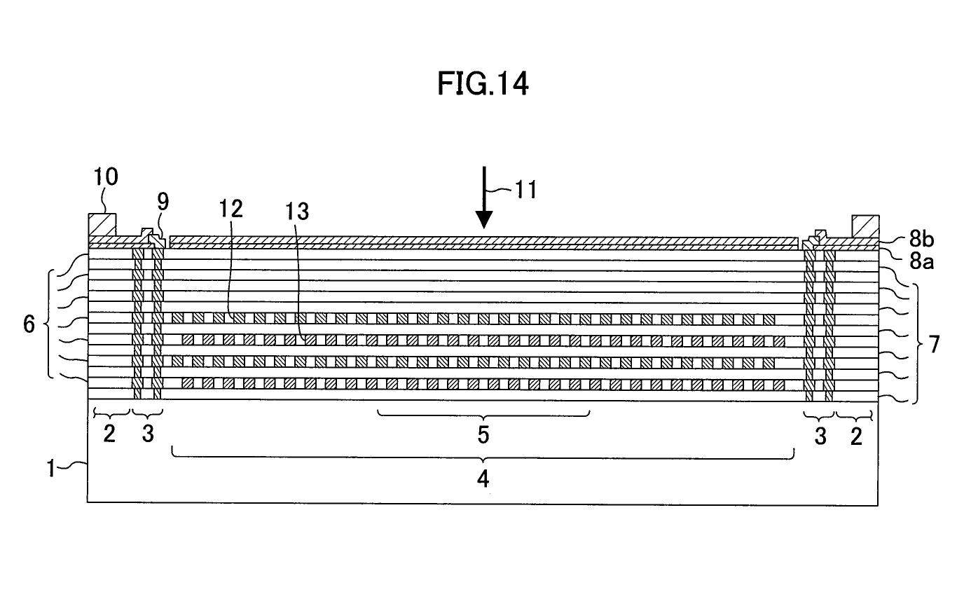

FIG. 14 is a cross-sectional view of a semiconductor device according to the sixth modification of the second embodiment and shows a scribe region 4 provided between the circuit regions 2.

As shown in FIG. 14, the semiconductor device of the sixth modification is characterized in that a first dummy pattern 12 and a second dummy pattern 13 are formed in the lower ones of a plurality of first interlayer insulating films 6 formed on a semiconductor substrate 1. In other words, a first dummy pattern 12 and a second dummy pattern 13 are formed in fine layers that are usually used for circuit formation.

With this structure, the first dummy pattern 12 and the second dummy pattern 13 cover the scribe region 4 with a finer pattern arrangement than in the case where the first dummy pattern 12 and the second dummy pattern 13 are formed in the upper ones of the plurality of first interlayer insulating films 6. Therefore, heat generation and melting of the interlayer insulating film can be more uniformly caused by laser light 11. Accordingly, the first interlayer insulating films 6 and the second interlayer insulating films 7 can be uniformly melted and removed by the laser light 11 in a wide range of the scribe region 4. A laser grooving process can thus be performed while preventing peeling of the interlayer insulating film.

Even when a diffusion layer conductive film is formed between the semiconductor substrate 1 and the interlayer insulating film, the interlayer insulating film has been melted and removed before the laser light 11 is emitted to the diffusion layer conductive film, as in the first modification of the second embodiment. Therefore, melting of the diffusion layer conductive film does not cause any influence on the interlayer insulating film, such as peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

In the sixth modification of the second embodiment, the first dummy pattern 12 and the second dummy pattern 13 are formed in the lower four of the first interlayer insulating films 6 which correspond to fine layers. However, the invention is not limited to this structure. The first dummy pattern 12 and the second dummy pattern 13 may alternatively be formed only in the lower two of the first interlayer insulating films 6, and a first interlayer insulating film 6 having no dummy pattern may be formed between the first interlayer insulating films 6 respectively having the first dummy pattern 12 and the second dummy pattern 13.

(Seventh Modification of the Second Embodiment)

A seventh modification of the second embodiment of the invention will now be described with reference to the figures.

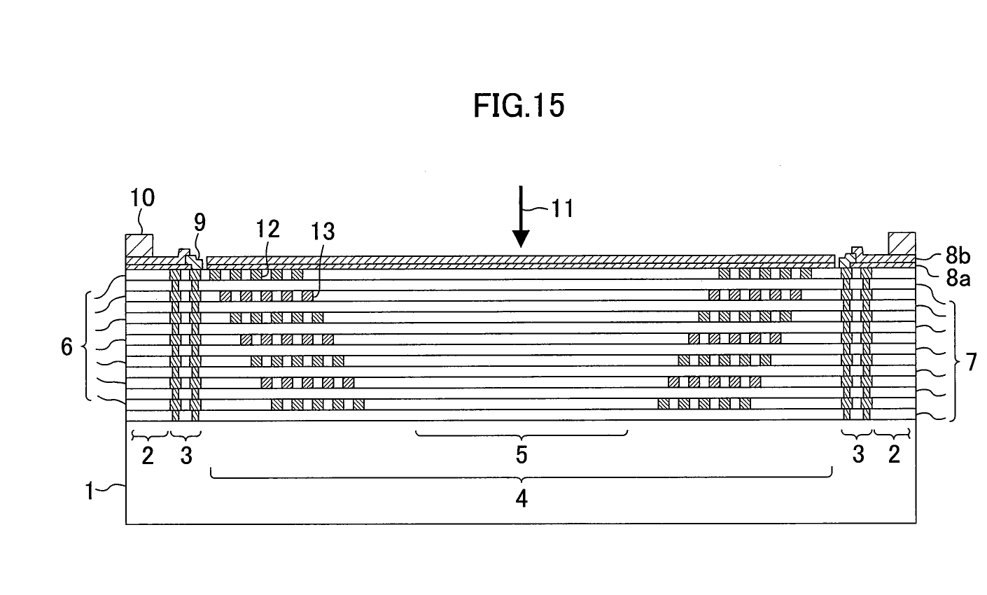

FIG. 15 is a cross-sectional view of a semiconductor device according to the seventh modification of the second embodiment and shows a scribe region 4 provided between adjacent circuit regions 2.

As shown in FIG. 15, a first dummy pattern 12 and a second dummy pattern 13 are formed in a plurality of first interlayer insulating films 6 formed on a semiconductor substrate 1 in a scribe region 4. The semiconductor device of the seventh modification is characterized in that the first dummy pattern 12 and the second dummy pattern 13 are formed in a region close to the seal ring 3 except for a blade dicing region 5. In other words, the first dummy pattern 12 and the second dummy pattern 13 are formed on both sides of the blade dicing region 5 in the scribe region 4. A no-dummy-pattern region including the blade dicing region 5 is increased toward the upper interlayer insulating films 6.

In this structure, the first interlayer insulating films 6 and the second interlayer insulating films 7 have almost no material that absorbs laser light 11 in the region to which laser light 11 is emitted. Moreover, since heat generated in the exothermic reaction caused by the laser light 11 is released in the opposite direction to the semiconductor substrate 1, a laser grooving process can be performed without damaging the semiconductor substrate 1.

Accordingly, the first interlayer insulating films 6 and the second interlayer insulating films 7 can be uniformly melted and removed by the laser light 11 in a wide range of the scribe region 4. A laser grooving process can thus be performed while preventing peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

In the seventh modification of the second embodiment, the first dummy pattern 12 and the second dummy pattern 13 are formed in the scribe region 4 other than the blade dicing region 5. However, the invention is not limited to this structure. Any structure may be used as long as the scribe region 4 other than the blade dicing region 5 is covered by a plurality of dummy patterns or a flat-plate dummy pattern.

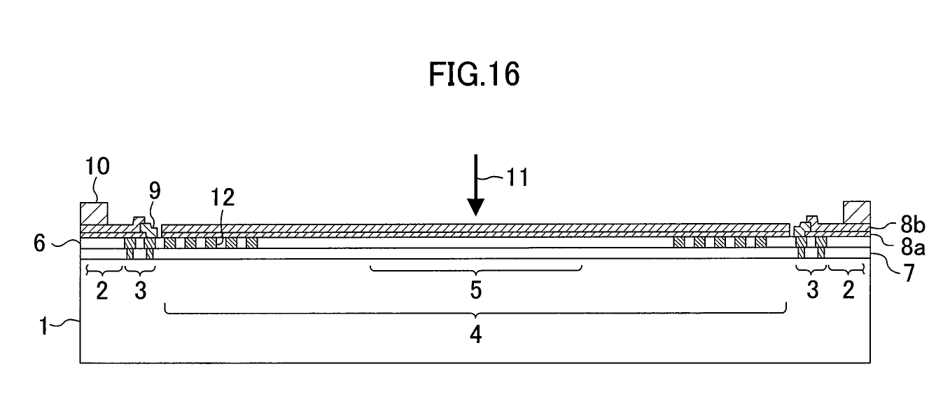

In the seventh modification of the second embodiment, the interlayer insulating film in the scribe region 4 is formed by a plurality of interlayer insulating films. As shown in FIG. 16, however, the interlayer insulating film may alternatively be formed by a first interlayer insulating film 6 and a second interlayer insulating film 7.

(Eighth Modification of the Second Embodiment)

An eighth modification of the second embodiment of the invention will now be described with reference to the figures.

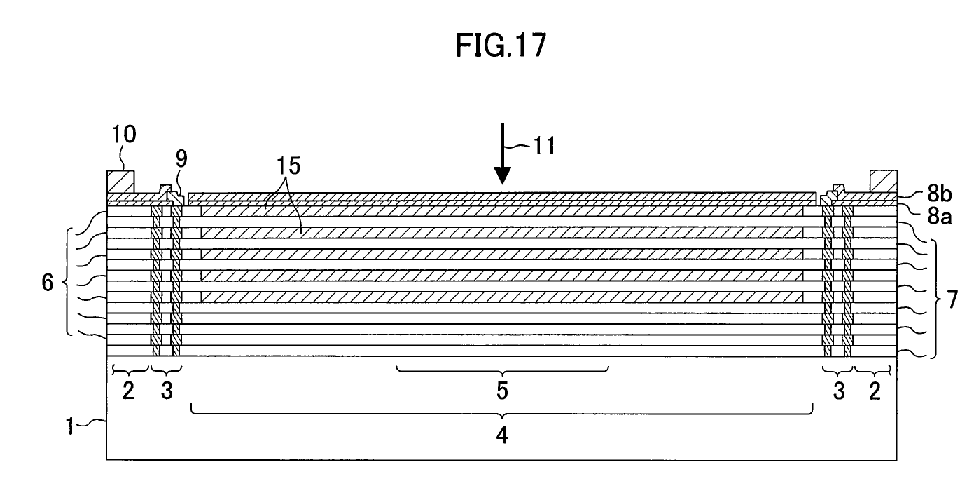

FIG. 17 is a cross-sectional view of a semiconductor device according to the eighth modification of the second embodiment and shows a scribe region 4 provided between adjacent circuit regions 2.

As shown in FIG. 17, the semiconductor device of the eighth modification is characterized in that a third dummy pattern 15 that covers the whole laser dicing region 5 is formed in the upper ones of a plurality of first interlayer insulating films 6 formed on a semiconductor substrate 1.

With this structure, laser light 11 emitted in a laser grooving process can be reliably blocked by the third dummy pattern 15 formed in the first interlayer insulating films 6. Melting of the third dummy pattern 15 by the laser light 11 sequentially proceeds from the upper first interlayer insulating films 6 toward the lower first interlayer insulating films 6. Therefore, the upper part of the interlayer insulating film has already been removed when the laser light 11 reaches a diffusion layer conductive film formed between the semiconductor substrate 1 and the interlayer insulating film. Accordingly, the first interlayer insulating films 6 and the second interlayer insulating films 7 can be uniformly melted and removed by the laser light 11 in a wide range of the scribe region 4. A laser grooving process can thus be performed while preventing peeling of the interlayer insulating film.

Even when the diffusion layer conductive film is formed between the semiconductor substrate 1 and the interlayer insulating film, the interlayer insulating film has been melted and removed before the laser light 11 is emitted to the diffusion layer conductive film, as in the first modification of the second embodiment. Therefore, melting of the diffusion layer conductive film does not cause any influence on the interlayer insulating film, such as peeling of the interlayer insulating film.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

In the eighth modification, the third dummy pattern 15 is formed in the upper five first interlayer insulating films 6. However, the invention is not limited to five films. There may be a first interlayer insulating film in the upper part of the interlayer insulating film which does not have the third dummy pattern 15. In other words, the third dummy pattern 15 need not necessarily be formed in successive first interlayer insulating films 6. The third dummy pattern 15 may be formed in the second interlayer insulating films 7.

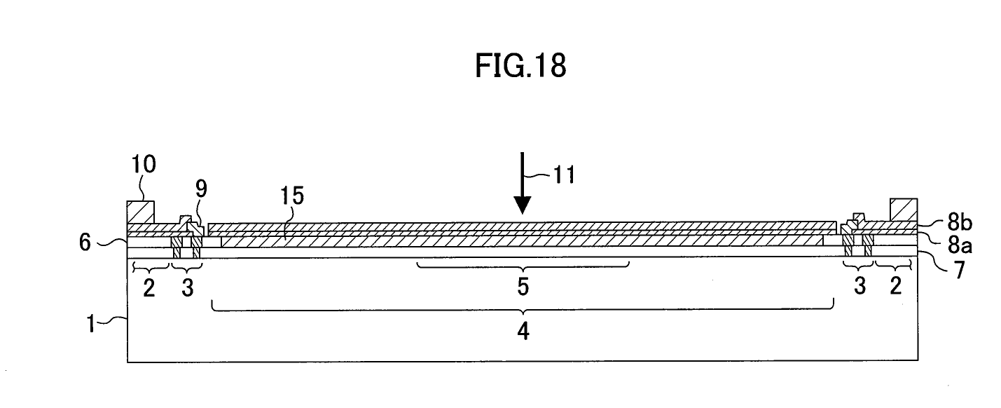

In the eighth modification of the second embodiment, the interlayer insulating film in the scribe region 4 is formed by a plurality of layers. As shown in FIG. 18, however, the interlayer insulating film may alternatively be formed by a first interlayer insulating film 6 and a second interlayer insulating film 7.

### Third Embodiment

A third embodiment of the invention will now be described with reference to the figures. In the third embodiment, the same elements as those of the first embodiment are denoted with the same reference numerals and characters, and description thereof will be omitted. In the third embodiment, a dummy pattern formed by dummy vias 16 is formed in a scribe region 4.

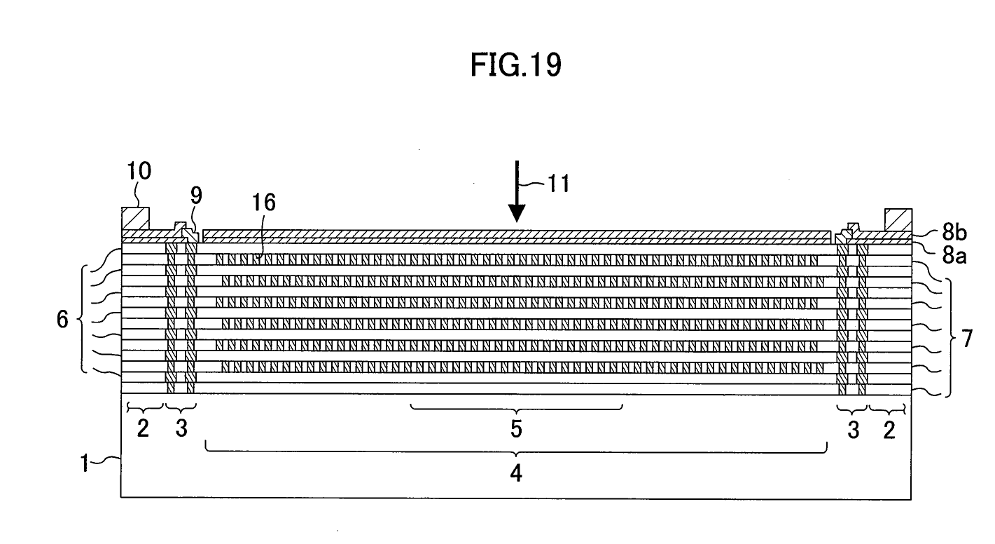

FIG. 19 shows a semiconductor device according to the third embodiment. FIG. 19 is a cross-sectional view of a scribe region 4 provided between adjacent circuit regions 2.

As shown in FIG. 19, in the semiconductor device of the third embodiment, a dummy pattern formed by a plurality of dummy vias 16 is formed in a plurality of first interlayer insulating films 6. The dummy pattern is formed so that every part of the scribe region 4, especially a blade dicing region 5, has dummy vias 16 when viewed two-dimensionally.

The dummy vias 16 are thus formed so as to cover the scribe region 4 when viewed two-dimensionally. Since the scribe region 4 is covered by a conductive material of the dummy vias 16, laser light 11 is blocked by the conductive material in a laser grooving process. Accordingly, in the laser grooving process, the laser light 11 is absorbed by the dummy pattern having a plurality of layers. As the laser light 11 is absorbed by the dummy pattern, heat is generated and the interlayer insulating film is melted. Note that copper, aluminum, tungsten, or the like is used as the conductive material.

The interlayer insulating film is melted as in the second embodiment. An upper part of the layered structure of the first interlayer insulating films 6 and the second interlayer insulating films 7 is first melted and the melted part is removed by sublimation. The melted part continuously expands in the layered structure of the first interlayer insulating films 6 and the second interlayer insulating films 7. As a result, the first interlayer insulating films 6 and the second interlayer insulating films 7 can be uniformly melted and removed by the laser light 11 in a wide range of the scribe region 4. Peeling of the interlayer insulating film can thus be prevented.

A finer dummy pattern can be formed by the dummy vias 16 than by an interconnect pattern because the height of the vias is smaller than the thickness of the interconnects. Therefore, pattern uniformity can be improved by using the dummy pattern formed by the dummy vias 16. Moreover, the dummy pattern formed by the dummy vias 16 improves uniformity of heat conduction during emission of the laser light. Accordingly, a laser grooving process can be performed efficiently.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

The dummy vias 16 of the dummy pattern can be formed in the scribe region 4 simultaneously with a process of forming a via pattern in the circuit regions 2 by a damascene process or the like, by using the same material.

In the third embodiment, the dummy vias 16 are formed only in the first interlayer insulating film 6. However, the dummy vias 16 may be formed in the second interlayer insulating films 7.

Although not shown in the figure, a diffusion layer conductive film may be formed between the semiconductor substrate and the interlayer insulating film, as in the first modification of the second embodiment. The interlayer insulating film has been melted and removed before laser light is emitted to the diffusion layer conductive film in the laser grooving process. Therefore, the interlayer insulating film is not affected by melting of the diffusion layer conductive film.

### Fourth Embodiment

A fourth embodiment of the invention will now be described with reference to the figures. In the fourth embodiment, the same elements as those of the first embodiment are denoted with the same reference numerals and characters, and description thereof will be omitted. In the fourth embodiment, a dummy pattern formed by dummy interconnects and dummy vias is formed in a scribe region 4.

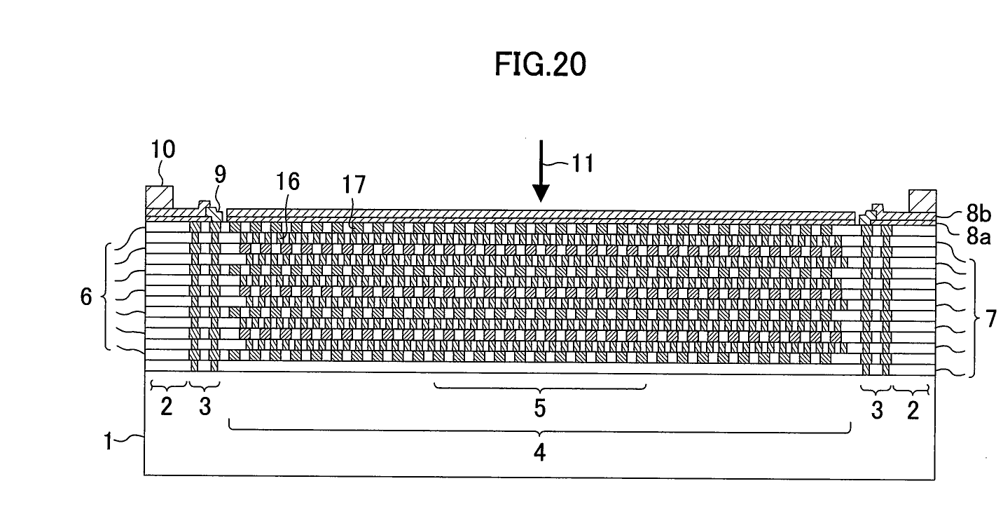

FIG. 20 shows a semiconductor device according to the fourth embodiment. FIG. 20 is a cross-sectional view of a scribe region 4 provided between adjacent circuit regions 2.

As shown in FIG. 20, in the semiconductor device of the fourth embodiment, a dummy pattern formed by dummy interconnects 17 and dummy vias 16 is formed in a plurality of first interlayer insulating films 6 and a plurality of second interlayer insulating films 7. The dummy interconnects 17 are connected to each other through corresponding dummy vias 16. The dummy interconnects 17 and the dummy vias 16 are formed so that every part of the scribe region 4, especially in a blade dicing region 5, has the dummy pattern when viewed two-dimensionally.

The dummy interconnects 17 and the dummy vias 16 are thus formed so as to cover the scribe region 4 when viewed two-dimensionally. In this case, the scribe region 4 is covered by a conductive material of the dummy interconnects 17 and the dummy vias 16, and laser light 11 is blocked by the conductive material in a laser grooving process. Accordingly, the laser light 11 is absorbed by the dummy interconnects 17 and the dummy vias 16 in the laser grooving process. As the laser light 11 is absorbed by the dummy interconnects 17 and the dummy vias 16, heat is generated and the interlayer insulating film is easily melted. Note that copper, aluminum, tungsten, or the like is used as the conductive material.

The interlayer insulating film is melted as in the second embodiment. An upper part of the layered structure of the first interlayer insulating films 6 and the second interlayer insulating films 7 is first melted and the melted part is removed by sublimation. The melted part continuously expands in the layered structure of the first interlayer insulating films 6 and the second interlayer insulating films 7. As a result, the first interlayer insulating films 6 and the second interlayer insulating films 7 can be uniformly melted and removed by the laser light 11 in a wide range of the scribe region 4. Peeling of the interlayer insulating film can thus be prevented.

Since the dummy interconnects 17 and the dummy vias 16 are connected, excellent thermal conductivity is obtained. Therefore, a melting property of the interlayer insulating film by the laser light 11 is improved, whereby the melted part is homogenized.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

The dummy interconnects 17 and the dummy vias 16 can be formed in the scribe region 4 simultaneously with a process of forming an interconnect pattern and a via pattern in the circuit regions 2 by a damascene process or the like, by using the same material.

Although not shown in the figure, a diffusion layer conductive film may be formed between the semiconductor substrate and the interlayer insulating film, as in the first modification of the second embodiment. The interlayer insulating film has been melted and removed before laser light is emitted to the diffusion layer conductive film in the laser grooving process. Therefore, the interlayer insulating film is not affected by melting of the diffusion layer conductive film.

(First Modification of the Fourth Embodiment)

A first modification of the fourth embodiment of the invention will now be described with reference to the figures. The first modification of the fourth embodiment is characterized in that a dummy pattern formed by dummy interconnects 17 and dummy vias 16 is formed especially in a blade dicing region 5 of a scribe region 4.

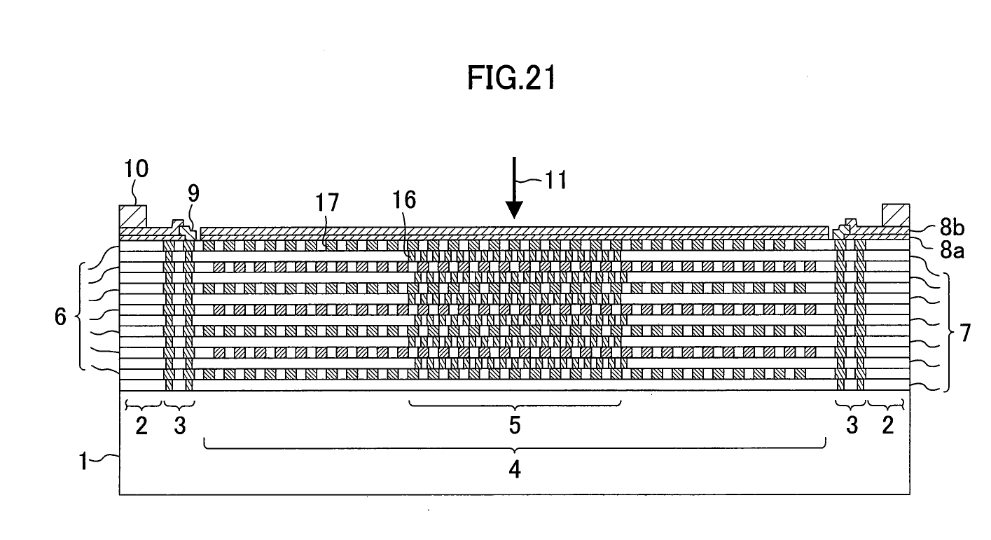

FIG. 21 shows a semiconductor device according to the first modification of the fourth embodiment. FIG. 21 is a cross-sectional view of a scribe region 4 provided between adjacent circuit regions 2.

As shown in FIG. 21, in the semiconductor device of the first modification of the fourth embodiment, dummy interconnects 17 are formed in the whole scribe region 4, and the dummy interconnects 17 are connected by corresponding dummy vias 16 in the blade dicing region 5 of the scribe region 4.

In this structure, the dummy interconnects 17 and the dummy vias 16 that are made of a conductive material are formed in the scribe region 4, especially the blade dicing region 5, to be melted by laser light 11. Therefore, excellent thermal conductivity is obtained. Accordingly, a melting property of the interlayer insulating film by the laser light 11 is improved, whereby the melted part is homogenized. Since the interlayer insulating film is uniformly removed by the laser light 11, peeling of the interlayer insulating film can be prevented. Moreover, influences caused by formation of the dummy pattern in the scribe region 4 can be suppressed in a blade dicing process.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

Although not shown in the figure, a diffusion layer conductive film may be formed between the semiconductor substrate and the interlayer insulating film, as in the first modification of the second embodiment. The interlayer insulating film has been melted and removed before laser light is emitted to the diffusion layer conductive film in the laser grooving process. Therefore, the interlayer insulating film is not affected by melting of the diffusion layer conductive film.

In the first modification of the fourth embodiment, the dummy interconnects 17 are formed in the whole scribe region 4 and the dummy interconnects 17 are connected to each other by corresponding dummy vias 16 in the blade dicing region 5. Alternatively, however, the dummy vias 16 may be formed in the whole scribe region 4 and the dummy interconnects 17 may be formed in the blade dicing region 5 and connected by corresponding dummy vias 16. In other words, the same effects can be obtained as long as the dummy interconnects 17 and the dummy vias 16 are formed in the blade dicing region 5 so that every part of the blade dicing region 5 has the dummy interconnects 17 or the dummy interconnects 16 when viewed two-dimensionally, and the dummy interconnects 17 and the dummy vias 16 are connected.

(Second Modification of the Fourth Embodiment)

A second modification of the fourth embodiment of the invention will now be described with reference to the figures. The second modification of the fourth embodiment is characterized in that a dummy pattern formed by dummy interconnects 17 and dummy vias 16 is formed in an upper part of an interlayer insulating film especially in a blade dicing region 5 of a scribe region 4.

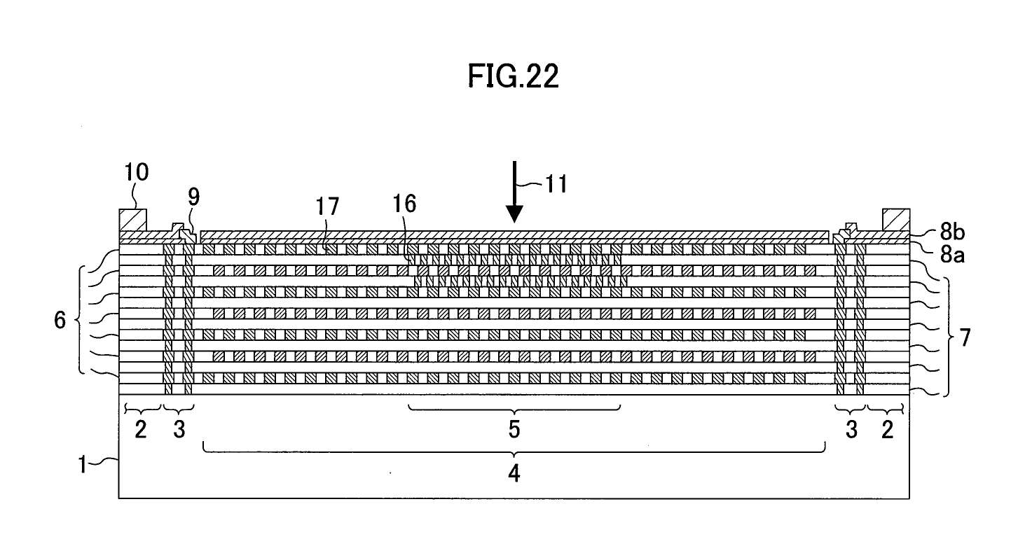

FIG. 22 shows a semiconductor device according to the second modification of the fourth embodiment. FIG. 22 is a cross-sectional view of a scribe region provided between adjacent circuit regions 2.

As shown in FIG. 22, in the semiconductor device of the second modification of the fourth embodiment, dummy interconnects 17 are formed in the whole scribe region 4, and the dummy interconnects 17 are connected by corresponding dummy vias 16 in the upper part of the interlayer insulating film in the blade dicing region 5 of the scribe region 4.

In this structure, the dummy interconnects 17 and the dummy vias 16 that are made of a conductive material are formed in the upper part of the interlayer insulating film in the scribe region 4, especially the blade dicing region 5, to be melted by laser light 11. Therefore, excellent thermal conductivity is obtained. Although not shown in details in the figure, the thickness of each layer of the interlayer insulating film is generally increased toward the top. In the case where the dummy interconnects 17 and the dummy vias 16 are formed in the upper layers of the interlayer insulating film in the blade dicing region 5, melting of the interlayer insulating film by the laser light 11 continuously expands from the top layer toward the bottom layer. Therefore, the interlayer insulating film can be uniformly melted in a wide range of the scribe region 4. Since a melting property of the interlayer insulating film by the laser light 11 is improved, the melted part is homogenized. Since the interlayer insulating film is uniformly removed by the laser light 11, peeling of the interlayer insulating film can be prevented.

A blade dicing process is then performed in the blade dicing region 5. As in the first embodiment, since the first interlayer insulating films 6 and the second interlayer insulating films 7 which are likely to generate chippings have already been removed in the blade dicing region 5 of the scribe region 4, only the semiconductor substrate 1 made of a single material needs to be cut in the blade dicing region 5 in the blade dicing process. Accordingly, possibility of generating chipping defects can be significantly reduced. Chipping defects can thus be prevented from being generated in a dicing process for cutting out the circuit regions 2 from the semiconductor substrate 1.

Although not shown in the figure, a diffusion layer conductive film may be formed between the semiconductor substrate and the interlayer insulating film, as in the first modification of the second embodiment. The interlayer insulating film has been melted and removed before laser light is emitted to the diffusion layer conductive film in the laser grooving process. Therefore, the interlayer insulating film is not affected by melting of the diffusion layer conductive film.

In the second modification of the fourth embodiment, the dummy interconnects 17 are formed in the whole scribe region 4, and the dummy interconnects 17 are connected to each other by corresponding dummy vias 16 in the upper layers of the interlayer insulating film in the blade dicing region 5. Alternatively, however, the dummy vias 16 may be formed in the whole scribe region 4, and the dummy interconnects 17 may be formed in the upper layers of the interlayer insulating film in the blade dicing region 5 and connected by corresponding dummy vias 16. In other words, the same effects can be obtained as long as the dummy interconnects 17 and the dummy vias 16 are formed in the upper layers of the interlayer insulating film in the blade dicing region 5 so that every part of the blade dicing region 5 has the dummy interconnects 17 or the dummy interconnects 16 when viewed two-dimensionally, and the dummy interconnects 17 and the dummy vias 16 are connected.

As has been described above, the semiconductor device of the invention can implement uniform removal of the interlayer insulating film in a wide range of the scribe region by the laser grooving process and can prevent peeling of the interlayer insulating film in the laser grooving process and the dicing process. Therefore, the invention is useful as a semiconductor device having a multilayer interconnect structure, and the like.

What is claimed is:

1. A semiconductor device, comprising:
a semiconductor substrate;
a diffusion layer conductive film formed on the semiconductor substrate;
an interlayer insulating film layered on the semiconductor substrate;
an interconnect pattern and a via pattern formed in the interlayer insulating film;
a plurality of circuit regions formed in the semiconductor substrate; and
a scribe region formed around the circuit regions and separating the circuit regions from each other, wherein
the diffusion layer conductive film is not formed at least in a region to which laser light is emitted in the scribe region.

2. The semiconductor device according to claim 1, wherein the diffusion layer conductive film is not formed in the scribe region.

3. The semiconductor device according to claim 1, wherein the interconnect pattern and the via pattern are not formed in the scribe region.

4. The semiconductor device according to claim 1, wherein the interconnect pattern or the via pattern is formed in the scribe region other than a region around a center line of the scribe region, and the interconnect pattern or the via pattern formed in the scribe region has an increased distance across the region around the center line toward a top layer of the interlayer insulating film.

5. A semiconductor device, comprising:
a semiconductor substrate;
a diffusion layer conductive film formed on the semiconductor substrate;
a plurality of interlayer insulating films layered on the semiconductor substrate;
an interconnect pattern and a via pattern formed in the interlayer insulating films;
a plurality of circuit regions formed in the semiconductor substrate; and
a scribe region formed around the circuit regions and separating the circuit regions from each other, wherein at least a region to which laser light is emitted in the scribe region is covered by the interconnect patterns or the via patterns respectively formed in a plurality of interlayer insulating films, when viewed two-dimensionally.

6. The semiconductor device according to claim 5, wherein the scribe region is entirely covered by the interconnect patterns or the via patterns respectively formed in the plurality of interlayer insulating films, when viewed two-dimensionally.

7. The semiconductor device according to claim 5, wherein the diffusion layer conductive film is formed in the scribe region.

8. The semiconductor device according to claim 5, wherein the interconnect patterns respectively formed in the plurality of interlayer insulating films in the scribe region overlap each other at least at their respective ends, when viewed two-dimensionally.

9. The semiconductor device according to claim 5, wherein the interconnect patterns respectively formed in the plurality of interlayer insulating films in the scribe region have their respective edges aligned each other, when viewed two-dimensionally.

10. The semiconductor device according to claim 5, wherein the interconnect pattern formed in the scribe region is formed in upper two or more of the plurality of interlayer insulating films.

11. The semiconductor device according to claim 5, wherein the interconnect pattern formed in the scribe region is formed in lower two or more of the plurality of interlayer insulating films.

12. A semiconductor device, comprising:
a semiconductor substrate;
a diffusion layer conductive film formed on the semiconductor substrate;
an interlayer insulating film layered on the semiconductor substrate and having an interconnect pattern;
a plurality of circuit regions formed in the semiconductor substrate; and
a scribe region formed around the circuit regions and separating the circuit regions from each other, wherein
the interconnect pattern having a flat plate shape is formed at least in a region to which laser light is emitted in the scribe region.

13. A semiconductor device, comprising:
a semiconductor substrate;
a diffusion layer conductive film formed on the semiconductor substrate;
an interlayer insulating film layered on the semiconductor substrate;
an interconnect pattern and a via pattern formed in the interlayer insulating film;
a plurality of circuit regions formed in the semiconductor substrate; and
a scribe region formed around the circuit regions and separating the circuit regions from each other, wherein
at least a region to which laser light is emitted in the scribe region is covered by the interconnect patterns and the via patterns respectively formed in a plurality of interlayer insulating films, when viewed two-dimensionally.

14. The semiconductor device according to claim 13, wherein the interconnect pattern and the via pattern are formed in the plurality of interlayer insulating films so as to cover the entire scribe region when viewed two-dimensionally.

15. The semiconductor device according to claim 13, wherein the interconnect pattern is formed in the entire scribe region, and the via pattern is formed only in an upper layer of the interlayer insulating film in a region around a central line of the scribe region.

16. The semiconductor device according to claim 13, wherein the diffusion layer conductive film is formed in the scribe region.

17. The semiconductor device according to claim 13, wherein the interconnect pattern and the via pattern are connected to each other.
